(19) United States
(12) Patent Application Publication
(10) Pub. No.: US 2024/0198658 A1
(43) Pub. Date: Jun. 20, 2024

(54) CONTROL UNIT AND SUBSTRATE TREATING APPARATUS INCLUDING THE SAME

(71) Applicant: SEMES CO., LTD., Chungcheongnam-do (KR)

(72) Inventor: Hyun Goo KWON, Gyeonggi-do (KR)

(21) Appl. No.: 18/544,422

(22) Filed: Dec. 18, 2023

(30) Foreign Application Priority Data
Dec. 20, 2022 (KR) 10-2022-0179767

(51) Int. Cl. B41J 2/045; B41J 2/21

(52) U.S. Cl. CPC B41J 2/0451; B41J 2/04581; B41J 2/2142

(57) ABSTRACT

There are provided a control unit and a substrate treating apparatus including the same, which manage the quality and lifespan of an inkjet head unit based on the position reproducibility of a substrate treating solution ejected by the inkjet head unit. The substrate treating apparatus includes: a process treatment unit supporting a substrate; an inkjet head unit ejecting a substrate treating solution onto the substrate in the form of a droplet; a gantry unit moving the inkjet head unit; and a control unit controlling the inkjet head unit, wherein the control unit determines whether to replace the inkjet head unit based on a position reproducibility of the droplet.

### CROSS-REFERENCE TO RELATED APPLICATION

This application claims priority from Korean Patent Application No. 10-2022-0179767 filed on Dec. 20, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a control unit and a substrate processing apparatus including the same, and more particularly, to a control unit and a substrate processing apparatus including the same, which are utilized in manufacturing a display device.

### 2. Description of the Related Art

When manufacturing a display device such as a liquid crystal display (LCD) panel, a light-emitting diode (LED) display panel, and an organic electroluminescent (EL) device, a printing process can be performed on a transparent substrate using inkjet equipment. The inkjet equipment can perform a patterning process (e.g., red-green-blue (RGB) patterning) at desired locations on the transparent substrate by ejecting fine ink droplets using an inkjet head.

The inkjet head plays the role of ejecting a treating solution onto the substrate for the patterning process. Therefore, determining the lifespan and replacement timing of the inkjet head is very important in minimizing the production of defective products.

When measuring the lifespan of the inkjet head, the number of times the treating solution is ejected from the inkjet head may be calculated, and the result of the calculation may be compared with a standard number provided by the manufacturer to determine the replacement timing of the inkjet head. However, the said standard number does not take into account the usage environment, such as the type of ink used, and therefore has inadequacies when used as a benchmark.

### SUMMARY

Aspects of the present disclosure provide a control unit and a substrate treating apparatus including the same, which manage the quality and lifespan of an inkjet head unit based on the position reproducibility of a substrate treating solution ejected by the inkjet head unit.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes: a process treatment unit supporting a substrate; an inkjet head unit ejecting a substrate treating solution onto the substrate in the form of a droplet; a gantry unit moving the inkjet head unit; and a control unit controlling the inkjet head unit, wherein the control unit determines whether to replace the inkjet head unit based on a position reproducibility of the droplet.

According to another aspect of the present disclosure, a control unit for controlling an inkjet head unit, which ejects a substrate treating solution onto a substrate for treating the substrate, includes: a droplet position acquisition module acquiring positions of a plurality of droplets; a statistical value calculation module calculating statistical values related to a position reproducibility of the droplets based on the positions of the droplets; a comparison module comparing the statistical values with a threshold value; and a processing module instructing the replacement of the inkjet head unit if the statistical values are determined to exceed the threshold value.

According to another aspect of the present disclosure, a substrate treating apparatus includes: a process treatment unit supporting a substrate; an inkjet head unit ejecting a substrate treating solution onto the substrate in the form of a droplet; a gantry unit moving the inkjet head unit; and a control unit controlling the inkjet head unit, wherein the control unit determines whether to replace the inkjet head unit based on a position reproducibility of the droplet, the inkjet head unit includes a plurality of packs, each of the packs includes a plurality of head modules, each of the head modules includes a plurality of nozzles, the packs are classified into multiple groups depending on colors of the substrate treating solution, the control unit includes a droplet position acquisition module, which acquires positions of a plurality of droplets, a statistical value calculation module, which calculates statistical values based on the positions of the droplets, a comparison module, which compares the statistical value with a threshold value, and a processing module, which instructs the replacement of the inkjet head unit if the statistical values exceed the threshold value, the statistical value calculation module calculates head-specific standard deviations for a plurality of head modules with a plurality of nozzles, pack-specific standard deviations for a plurality of packs with a plurality of head modules, and color-specific standard deviations by classifying the plurality of packs by color, the statistical value calculation module calculates the pack-specific standard deviations based on the head-specific standard deviations and calculates the color-specific standard deviations based on the pack-specific standard deviations, the comparison module determines whether each of the head-specific standard deviations, pack-specific standard deviations, and color-specific standard deviations exceed the threshold value, and if any one of the head-specific standard deviations, pack-specific standard deviations, and color-specific standard deviations is determined to exceed the threshold value, the processing module instructs the replacement of a corresponding component within the inkjet head unit.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first exemplary schematic view illustrating the internal configuration of a substrate treating apparatus that treats a substrate using an inkjet method;

FIG. 2 is a second exemplary schematic view illustrating the internal configuration of the substrate treating apparatus that treats a substrate using an inkjet method;

FIG. 3 is an exemplary schematic view illustrating a control unit that controls the components of the substrate treating apparatus;

FIG. 4 is a block diagram illustrating the internal modules of the control unit that constitutes the substrate treating apparatus;

FIG. 5 is a first exemplary schematic view illustrating the functions of the statistical value calculation module that constitutes the control unit;

FIG. 6 is a second exemplary schematic view illustrating the functions of the statistical value calculation module that constitutes the control unit;

FIG. 7 is a third exemplary schematic view illustrating the functions of the statistical value calculation module that constitutes the control unit;

FIG. 8 is an exemplary schematic diagram showing a head-specific standard deviation trend, which is derived based on experimental results for each head installed in a pack within an inkjet head unit;

FIG. 9 is an exemplary schematic diagram illustrating a pack-specific standard deviation trend, which is derived based on experimental results for each pack installed in the inkjet head unit;

FIG. 10 is an exemplary diagram showing a color-specific standard deviation trend, which is derived based on experimental results for a plurality of packs provided in the inkjet head unit for the respective colors;

FIG. 11 is a flowchart illustrating the operating method of the control unit that constitutes the substrate treating apparatus; and

FIG. 12 is a flowchart illustrating a statistical value calculation method of a statistical value calculation module that constitutes the control unit.

### DETAILED DESCRIPTION

Exemplary embodiments of the present disclosure will hereinafter be described with reference to the accompanying drawings. Like reference numerals indicate like elements through the specification, and thus, detailed descriptions thereof will be omitted.

The present disclosure relates to a substrate treating apparatus and method, which are utilized in manufacturing a display device, and more particularly, to a substrate treating apparatus and method that pattern a substrate by ejecting liquid droplets onto the substrate using an inkjet method. A detailed explanation of the present disclosure will be provided below with reference to the drawings.

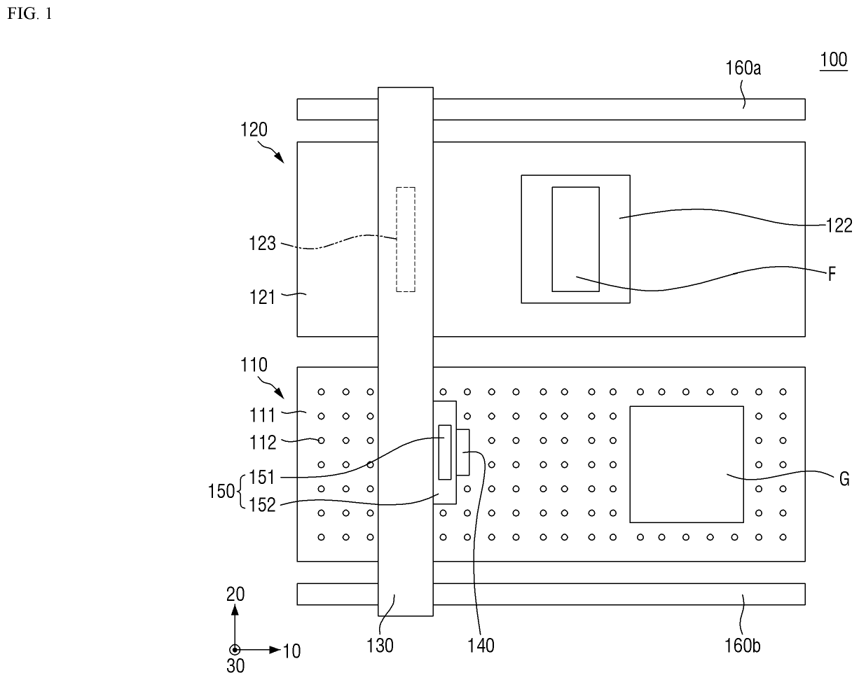

FIG. 1 is a schematic view illustrating the internal configuration of a substrate treating apparatus that treats a substrate using an inkjet method. Referring to FIG. 1, a substrate treating apparatus 100 may include a process treatment unit 110, a maintenance unit 120, a gantry unit 130, an inkjet head unit 140, and a substrate treating solution supply unit 150.

The substrate treating apparatus 100 can process a substrate G, which is used to manufacture a display device. The substrate treating apparatus 100 may be provided as inkjet printing equipment that performs a printing process on the substrate G by ejecting a substrate treating solution onto the substrate G using the inkjet head unit 140. The substrate G may be, for example, transparent glass.

The substrate treating solution is a solution used for printing the substrate G. The substrate treating apparatus 100 may use ink as the substrate treating solution. The substrate treating solution may be, for example, quantum dot (QD) ink containing ultrafine semiconductor particles. The substrate treating apparatus 100 may print pixels in various colors on the substrate G, and may form color filters on the substrate G. Additionally, the substrate treating apparatus 100 may be provided as circulation equipment to prevent nozzles within the inkjet head unit 140 from being clogged by the ink.

The process treatment unit 110 supports the substrate G during the treatment with the substrate treating solution. The process treatment unit 110 may support the substrate G using either a contact or non-contact method. When using the contact method, the process treatment unit 110 may support the substrate G by, for example, adhering the substrate G to a chuck equipped with a flat mounting surface thereon. When using the non-contact method, the process treatment unit 110 may support the substrate G by levitating the substrate G using air.

The process treatment unit 110 may move the substrate G from one direction to another direction while supporting the substrate G. The process treatment unit 110 may include, for example, a first stage 111 and air holes 112.

The first stage 111 may serve as a base and may be designed to have the substrate G mounted thereon. A plurality of air holes 112 may be formed within a printing zone on the first stage 111 to penetrate through the upper and lower parts of the first stage 111.

The air holes 112 may spray air in an upward direction (e.g., a third direction 30) of the first stage 111. As a result, the air holes 112 can levitate the substrate G mounted on the first stage 111.

Although not illustrated in FIG. 1, the process treatment unit 110 may further include a gripper and a guide rail. The gripper holds the substrate G and thereby prevents the substrate G from falling off of the first stage 111 as it moves along the length direction (e.g., a first direction 10) of the first stage 111. When the substrate G is moving, the gripper may hold the substrate G and move along the guide rail in the same direction as the substrate G. The gripper and the guide rail may be located on the outside of the first stage 111.

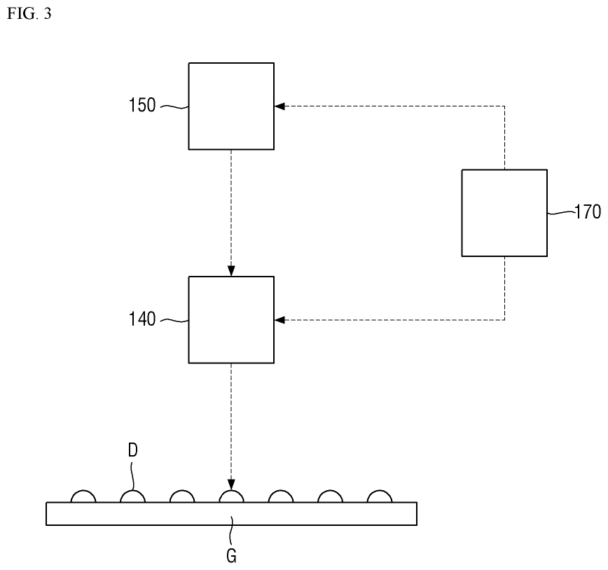

The maintenance unit 120 performs maintenance for the substrate G. For example, the maintenance unit 120 may measure whether the substrate treating solution is being ejected onto the substrate G in droplet form, the landing position (or ejection position), volume, area, and speed of each droplet, and can provide the results of the measurement to a control unit (“170” of FIG. 3), which will be described later.

The maintenance unit 120 may include a second stage 121, a measurement module 122, and a vision module 123, which is for inspecting droplets. Here, the second stage 121, like the first stage 111, may serve as a base and may be arranged parallel to the first stage 111. The second stage 121 may include a maintenance zone on its upper part. The second stage 121 may have the same size as or a different size from the first stage 111.

The measurement module 122 and the vision module 123 directly inspect droplets. Only the vision module 123 may be used for the inspection of droplets, in which case, the maintenance unit 120 may not include the measurement module 122. Alternatively, only the measurement module 122 may be used for the inspection of droplets, in which case, the maintenance unit 120 may not include the vision module 123.

The measurement module 122 may include a dummy substrate F through which the substrate treating solution is ejected. The dummy substrate F may be used for droplet inspection and may be in film form. The measurement module 122 may be provided as, for example, as a jetting-on-film (JOF) module. The measurement module 122 may also include a calibration board that features alignment marks, scales, and the like, for the purpose of measuring the landing position of each droplet.

The vision module 123 captures droplet-related images when the substrate treating solution is ejected onto the dummy substrate F for inspection purposes. To this end, the vision module 123 may include a camera and may be provided as, for example, a nozzle jetting inspection (NJI) module.

The vision module 123 may capture droplet-related images in real-time when the substrate treating solution is ejected onto the dummy substrate F for inspection purposes. The vision module 123 may obtain the droplet-related images by capturing images along the length direction (e.g., the first direction 10) of the dummy substrate F, in which case, the vision module 123 may include a line scan camera. Alternatively, the vision module 123 may obtain the droplet-related images by capturing images in units of areas of the dummy substrate F with a predetermined size, in which case, the vision module 123 may include an area scan camera.

The vision module 123 may acquire images of the dummy substrate F, which is for inspection purposes, on the maintenance unit 120, but the present disclosure is not limited thereto. The vision module 123 may also capture images of the substrate G, which is for production purposes, when the substrate G is being treated on the process treatment unit 110. For this purpose, the vision module 123 may be installed on the lower or side surface of the gantry unit 130, but the present disclosure is not limited thereto. The vision module 123 may also be installed on the front or side surface of the inkjet head unit 140 or may be provided on the gantry unit 130 or the inkjet head unit 140 to be movable, rather than fixed.

Although not illustrated in FIG. 1, the maintenance unit 120 may include a guide rail that can guide the movement path of the measurement module 122. The guide rail may be provided to guide the measurement module 122 in the length direction (e.g., the first direction 10) of the second stage 121 or the width direction (e.g., a second direction 20) of the second stage 121. For example, the maintenance unit 120 may be provided as a linear motion (LM) guide system.

The gantry unit 130 supports the inkjet head unit 140. The gantry unit 130 may be positioned above the first and second stages 111 and 121 to allow the inkjet head unit 140 to eject the substrate treating solution onto the substrates G and F.

The gantry unit 130 may be disposed on the first and second stages 111 and 121 with the width direction (e.g., the second direction 20) of the first and second stages 111 and 121 as its length direction. The gantry unit 130 may move along the length direction (e.g., the first direction 10) of the first and second stages 111 and 121, while being guided by first and second guide rails 160a and 160b. The first and second guide rails 160a and 160b may be provided on the outside of the first and second stages 111 and 121 along the length direction (e.g., the first direction 10) of the first and second stages 111 and 121. The first and second guide rails 160a and 160b may be provided as LM guide systems.

Although not illustrated in FIG. 1, the substrate treating apparatus 100 may further include a gantry moving unit. The gantry moving unit controls the gantry unit 130 to slidably move along the first and second guide rails 160a and 160b. The gantry moving unit may include a motor and may be installed within the gantry unit 130. Alternatively, the gantry moving unit may also be provided on the outside of the gantry unit 130.

The inkjet head unit 140 ejects the substrate treating solution onto the substrate G in droplet form. The inkjet head unit 140 may be installed on the side or lower surface of the gantry unit 130.

At least one inkjet head unit 140 may be installed on the gantry unit 130. When a plurality of inkjet head units 140 are installed on the gantry unit 130, the plurality of inkjet head units 140 may be arranged in a row along the length direction (e.g., the second direction 20) of the gantry unit 130. Furthermore, the plurality of inkjet head units 140 may operate independently. Alternatively, the plurality of inkjet head units 140 may operate in a unified manner.

The inkjet head unit 140 may move along the length direction (e.g., the second direction 20) of the gantry unit 130 to be positioned at a desired point on the substrate G. Additionally, the inkjet head unit 140 may move along the height direction (e.g., the third direction 30) of the gantry unit 130 and may also rotate either clockwise or counterclockwise. Meanwhile, the inkjet head unit 140 may also be fixed to the gantry unit 130, in which case, the gantry unit 130 may be provided to be movable on the substrate G.

Although not illustrated in FIG. 1, the substrate treating apparatus 100 may further include an inkjet head moving unit. The inkjet head moving unit may linearly move or rotate the inkjet head unit 140.

The substrate treating solution supply unit 150 may be provided as a reservoir for supplying the substrate treating solution to the inkjet head unit 140. The substrate treating solution supply unit 150 may be installed on the gantry unit 130 and may be configured to include a storage tank 151 and a pressure control module 152.

The storage tank 151 stores the substrate treating solution, and the pressure control module 152 regulates the internal pressure of the storage tank 151. The storage tank 151 may supply an appropriate amount of substrate treating solution to the inkjet head unit 140 based on the pressure provided by the pressure control module 152.

The substrate treating solution supply unit 150 may be integrated as a single module with the inkjet head unit 140. For example, the substrate treating solution supply unit 150 and the inkjet head unit 140 may be disposed on the front surface of the gantry unit 130, and the substrate treating solution supply unit 150 may be placed on a higher level than the inkjet head unit 140.

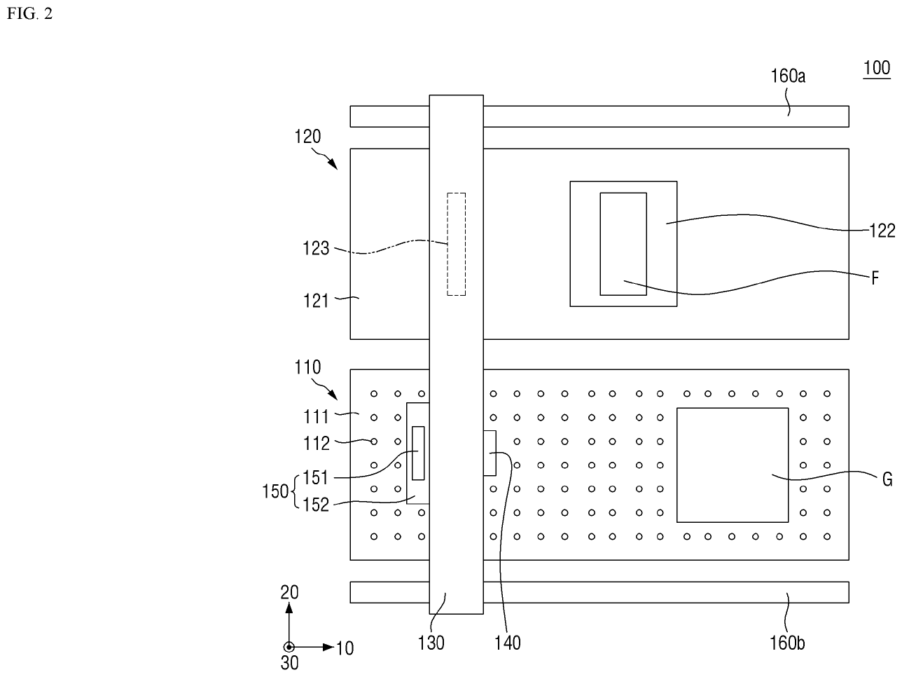

However, the present disclosure is not limited to this. The substrate treating solution supply unit 150 may also be configured as a separate module from the inkjet head unit 140. For example, as illustrated in FIG. 2, the substrate treating solution supply unit 150 and the inkjet head unit 140 may be disposed at the front and rear, respectively, of the gantry unit 130. FIG. 2 is a second exemplary schematic view illustrating the internal configuration of the substrate treating apparatus that treats a substrate using an inkjet method.

The substrate treating apparatus 100 may be provided as a piezoelectric inkjet printing system. In this case, the substrate treating apparatus 100 may drop droplets of the substrate treating solution onto the substrate G through the nozzles of the inkjet head unit 140 based on the voltage applied to piezoelectric elements.

The substrate treating apparatus 100 may also be provided as an electro-hydro-dynamic (EHD) inkjet printing system. In this case, when the substrate treating solution is exposed to a strong local electric field, a resulting electrostatic force exerts upon and induces charging in the substrate treating solution. Then, the substrate treating apparatus 100 may eject the substrate treating solution onto the substrate G due to an electrostatic mutual attraction caused by the charge injected into the substrate treating solution. That is, the substrate treating apparatus 100 may provide the substrate treating solution in the form of a Taylor cone based on the difference in voltage (e.g., pulse direct current (DC) voltage) between the inkjet head unit 140 and the substrate G, and the substrate treating solution may be ejected from the nozzles to form a printed line on the substrate G.

When the substrate treating apparatus 100 is configured as a piezoelectric inkjet printing system, the inkjet head unit 140 may be configured to include piezoelectric elements, a nozzle plate, and a plurality of nozzles. The nozzle plate forms the body, and the nozzles may be arranged in multiple rows and columns underneath the nozzle plate to be a predetermined distance apart from the nozzle plate. A number of piezoelectric elements corresponding to the number of nozzles may be provided. In this case, the inkjet head unit 140 may eject the substrate treating solution onto the substrate G through the nozzles, based on the operation of the piezoelectric elements.

Meanwhile, the inkjet head unit 140 may independently control the amount of substrate treating solution ejected through each of the nozzles based on the voltage applied to the corresponding piezoelectric element.

The substrate treating apparatus 100 may further include the control unit 170 to control the components of the substrate treating apparatus 100. For example, referring to FIG. 3, the control unit 170 may control both the inkjet head unit 140, which ejects droplets D onto the substrate G, and the substrate treating solution supply unit 150, which provides the substrate treating solution to the inkjet head unit 140. FIG. 3 is an exemplary schematic view illustrating the control unit that controls the components of the substrate treating apparatus.

The control unit 170 controls the overall operations of the components of the substrate treating apparatus 100. As mentioned earlier, the control unit 170 may control the overall operations of the inkjet head unit 140 and the substrate treating solution supply unit 150, but also the overall operations of the process treatment unit 110, the maintenance unit 120, and the gantry unit 130.

The control unit 170 may include: a process controller, which consists of a microprocessor (or a computer) that executes the control of the semiconductor treating apparatus 100; a user interface, which includes a keyboard for an operator to input commands and manage the semiconductor treating apparatus 100 and a display to visualize the operating status of the semiconductor treating apparatus 100; and a memory unit, which stores control programs for executing processes under the control of the process controller or programs (or processing recipes) for executing processes in the semiconductor treating apparatus 100 based on various data and processing conditions. The user interface and the memory unit may be connected to the process controller. The processing recipes may be stored on a storage medium within the memory unit, and the storage medium may be a hard disk, a removable disc such as a compact disc read-only memory (CD-ROM) or a digital versatile disc (DVD), or a semiconductor memory such as a flash memory.

The control unit 170 may also perform maintenance for the inkjet head unit 140. For example, the control unit 170 may calibrate the ejection positions of the nozzles in the inkjet head unit 140 or detect and initiate a cleaning process for any defective nozzles that do not eject the substrate treating solution based on measurement results from the measurement module 122 or the vision module 123.

As previously explained, in order to minimize the production of defective products (i.e., defective display devices) and thereby maximize the production of good-quality products while preventing increases in tact time due to process delays, it is necessary to monitor the lifespan of the inkjet head unit 140 in real-time. The substrate treating apparatus 100 can manage the quality and lifespan of the inkjet head unit 140 based on the position reproducibility of the substrate treating solution (i.e., the droplets D). This will hereinafter be described in further detail.

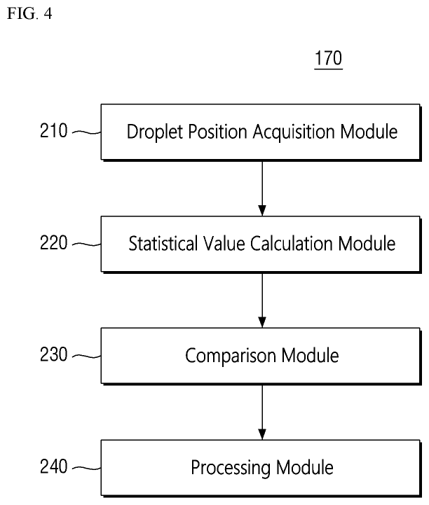

FIG. 4 is a block diagram illustrating the internal modules of the control unit that constitutes the substrate treating apparatus. Referring to FIG. 4, the control unit 170 may be configured to include a droplet position acquisition module 210, a statistical value calculation module 220, a comparison module 230, and a processing module 240.

The control unit 170 may manage the quality and lifespan of the inkjet head unit 140 based on the position reproducibility of droplets D. Specifically, the control unit 170 may measure the landing positions of droplets D ejected from the inkjet head unit 140, may identify related statistical values, and may determine and predict the quality of the inkjet head unit 140 based on standard deviation data among the statistical values. The control unit 170 may utilize the position reproducibility of the droplets D to minimize the constraints of the operating environment for the inkjet head unit 140, and efficiently operate the quality management of the inkjet head unit 140 by using the standard deviation data as a universal index for the position reproducibility of the droplets D.

The droplet position acquisition module 210 acquires information regarding the positions of the droplets D. The inkjet head unit 140 may move to where the maintenance unit 120 is positioned, and may eject the droplets D onto the dummy substrate F provided within the measurement module 122. In this case, the inkjet head unit 140 may eject a plurality of droplets D onto different positions on the dummy substrate F, but the present disclosure is not limited thereto. Alternatively, the inkjet head unit 140 may eject a single droplet D onto a predetermined position on the dummy substrate F. Alternatively, the inkjet head unit 140 may also eject a plurality of droplets D onto a single designated position on the dummy substrate F.

The inkjet head unit 140 will hereinafter be described as ejecting a plurality of droplets D onto different positions on the dummy substrate F, but the present disclosure may also be directly applicable to cases where a single droplet D or multiple droplets D are ejected onto a predetermined position or a single designated position on the dummy substrate F.

Meanwhile, the dummy substrate F, which is provided within the measurement module 122, may be a substrate coated with a hydrophobic material to easily distinguish the positions of the droplets D. For example, the dummy substrate F may be a hydrophobically coated film or jetting film.

When a plurality of droplets D are ejected onto the dummy substrate F by the inkjet head unit 140, the vision module 123 may measure the positions of the droplets D on the dummy substrate F under the control of the control unit 170. The droplet position acquisition module 210 may acquire information on the positions of the droplets D ejected onto the dummy substrate F in coordination with the measurement module 122 and the vision module 123. The droplet position acquisition module 210 may acquire the information on the positions of the droplets D as coordinate information (e.g., (x, y)) in a plane.

The statistical value calculation module 220 calculates statistical values related to the landing positions of the droplets D, acquired by the droplet position acquisition module 210.

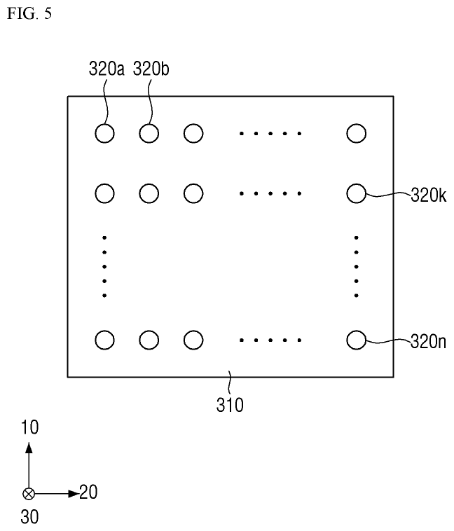

A plurality of packs may be installed in the inkjet head unit 140, and a plurality of head modules may be installed in each of the packs. Also, a plurality of nozzles (320a, 320b, . . . , 320k, . . . , and 320n) may be disposed in each of the head modules. Referring to FIG. 5, the nozzles (320a, 320b, . . . , 320k, . . . , and 320n) may be arranged in multiple rows and columns on the lower surface of a head module 310 to eject the substrate treating solution onto the substrate G. Some of the packs may eject the substrate treating solution of the same color, and other packs may eject the substrate treating solution of a different color. For example, the former packs may eject red color ink, and the latter packs may eject blue color ink. FIG. 5 is a first exemplary schematic view illustrating the functions of the statistical value calculation module that constitutes the control unit.

A case where 25 nozzles are disposed in the head module 310 and are arranged in five rows and five columns will hereinafter be described.

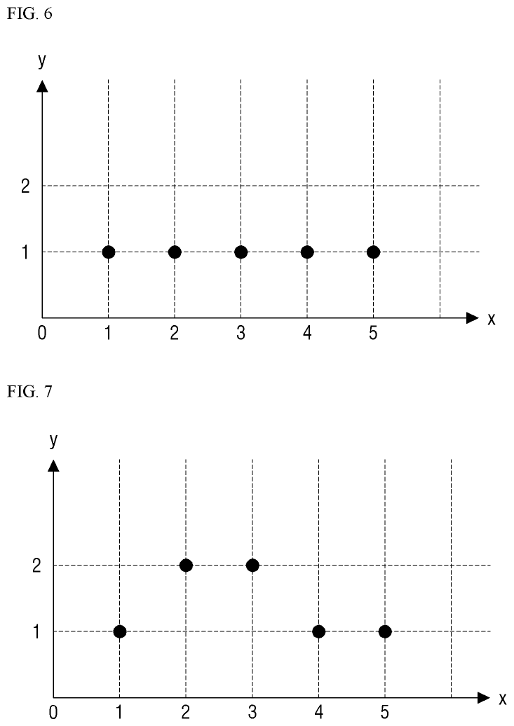

The statistical value calculation module 220 calculates the average value of the positions of droplets D ejected by five nozzles arranged in the first row of the head module 310. Ideally, referring to FIG. 6, the five nozzles in the first row of the head module 310 may eject the substrate treating solution onto positions (1, 1), (2, 1), (3, 1), (4, 1), and (5, 1). FIG. 6 is a second exemplary schematic view illustrating the functions of the statistical value calculation module that constitutes the control unit.

Referring to FIG. 7, if the five nozzles in the first row of the head module 310 eject the substrate treating solution at the positions (1, 1), (2, 2), (3, 2), (4, 1), (5, 1), the statistical value calculation module 220 calculates the average value of 1, 2, 2, 1, and 1. The statistical value calculation module 220 may also calculate the median value of 1, 2, 2, 1, and 1. For example, the statistical value calculation module 220 may calculate a median value of 1.5 from the largest and smallest values of 2 and 1. FIG. 7 is a third exemplary schematic view illustrating the functions of the statistical value calculation module that constitutes the control unit.

Once the average value is calculated, the statistical value calculation module 220 calculates a standard deviation based on the calculated average value. That is, the statistical value calculation module 220 calculates a column-specific standard deviation based on the center value position of each individual nozzle. The calculated standard deviation is related to the five nozzles in the first row.

The statistical value calculation module 220 calculates standard deviations in the same manner for five nozzles in each of second, third, fourth, and fifth rows of the head module 310.

The statistical value calculation module 220 may calculate an average value for a plurality of nozzles in each row and may calculate standard deviations based on the calculated average value, but the present disclosure is not limited thereto. Alternatively, the statistical value calculation module 220 may calculate standard deviations by applying the average value obtained from the first row to the second, third, fourth, and fifth rows.

Once the standard deviations for the respective rows of nozzles are calculated, the statistical value calculation module 220 calculates the average value of the calculated standard deviations as the standard deviation for the head module 310. That is, the statistical value calculation module 220 may calculate the standard deviation for each individual head based on the average value of column-specific standard deviations, but the present disclosure is not limited thereto. Alternatively, the statistical value calculation module 220 may calculate an average value for all the nozzles within the head module 310, may calculate a standard deviation based on the calculated average value, and may determine the calculated standard deviation as the standard deviation for the head module 310.

Once the standard deviation for a plurality of nozzles disposed in a particular head module is calculated, the statistical value calculation module 220 calculates standard deviations in the same manner for other head modules installed in the same pack as the particular head module, but the present disclosure is not limited thereto. Alternatively, the statistical value calculation module 220 may calculate standard deviations by applying the average value obtained from the particular head module to other head modules.

When the standard deviations for the respective head modules are calculated, the statistical value calculation module 220 calculates the average value of the calculated standard deviations as the standard deviation for the corresponding pack. That is, the statistical value calculation module 220 may calculate the standard deviation for a particular pack based on the average value of standard deviations for individual head modules included in the particular pack, but the present disclosure is not limited thereto. Alternatively, the statistical value calculation module 220 may calculate the average values for all the nozzles within the particular pack and may determine the standard deviation of the calculated average values as the standard deviation for the particular pack.

Once the standard deviation for the particular pack is calculated in the aforementioned manner, the statistical value calculation module 220 calculates standard deviation in the same manner for other packs installed in the inkjet head unit 140, but the present disclosure is not limited thereto. Alternatively, the statistical value calculation module 220 may calculate the standard deviations for the other packs by applying the average values obtained from the particular pack.

Once the standard deviations for a plurality of packs installed in the inkjet head unit 140 are calculated, the statistical value calculation module 220 may calculate color-specific standard deviations based on the calculated standard deviations. For example, if five packs, i.e., first, second, third, fourth, and fifth packs, are installed in the inkjet head unit 140 and the first and fourth packs eject red color ink, then the statistical value calculation module 220 may calculate a red color-related standard deviation based on the standard deviations for the first and fourth packs. That is, the statistical value calculation module 220 may calculate the standard deviation for each color based on the average value of the standard deviations for corresponding packs.

Referring back to FIG. 4, the comparison module 230 compares a statistical value (or number) calculated by the statistical value calculation module 220 with a management threshold value. Then, the comparison module 230 may determine whether the calculated statistical value exceeds the management threshold value based on the results of the comparison.

The comparison module 230 may determine whether the calculated statistical value for each individual head module exceeds the management threshold value, but the present disclosure is not limited thereto. Alternatively, the comparison module 230 may also determine whether the calculated statistical value for each individual pack exceeds the management threshold values. Yet alternatively, the comparison module 230 may also determine whether the calculated statistical value for each inkjet head unit 140 exceeds the management threshold value.

The processing module 240 determines the replacement timing for the inkjet head unit 140 based on the results of the determination performed by the comparison module 230. If it is determined by the comparison module 230 that the calculated statistical value exceeds the management threshold value, the processing module 240 may instruct the replacement of the inkjet head unit 140. Alternatively, if it is determined by the comparison module 230 that the calculated statistical value does not exceed the management threshold value, the processing module 240 may not instruct the replacement of the inkjet head unit 140.

The processing module 240 may instruct the replacement of the inkjet head unit 140, but the present disclosure is not limited thereto. Alternatively, the processing module 240 may also instruct the replacement of each individual pack. Yet alternatively, the processing module 240 may also instruct the replacement of packs corresponding to each particular color.

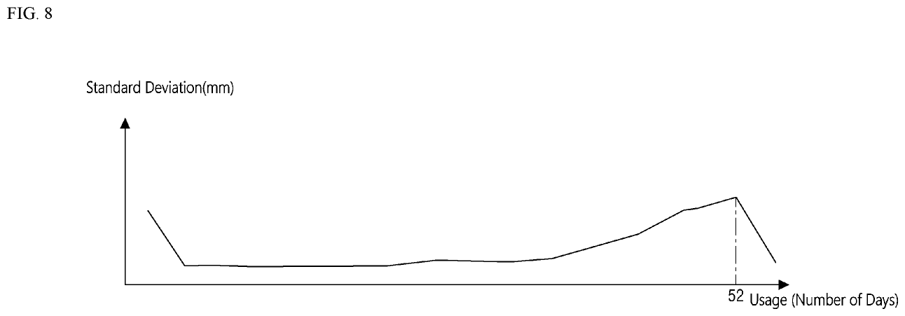

FIG. 8 is an exemplary schematic diagram showing a head-specific standard deviation trend, which is derived based on experimental results for each head installed in a pack within the inkjet head unit 140. Since experimental results for each head show a similar or identical shape to the broken line graph depicted in FIG. 8, only one representative experimental result is shown in the example of FIG. 8.

Referring to FIG. 8, it can be seen that the landing standard deviation for each individual head decreases upon head replacement and increases over the period of usage. The comparison module 230 may determine which part of the graph in FIG. 8 the statistical value calculated by the statistical value calculation module 220 corresponds to, and whether the corresponding statistical value exceeds the management threshold value. If it is determined, based on previously and currently calculated statistical values, that the period of usage has exceeded 52 days based on previous and current statistical values, the processing module 240 may instruct the replacement of the inkjet head unit 140. Alternatively, the processing module 240 may instruct the replacement of the corresponding head module.

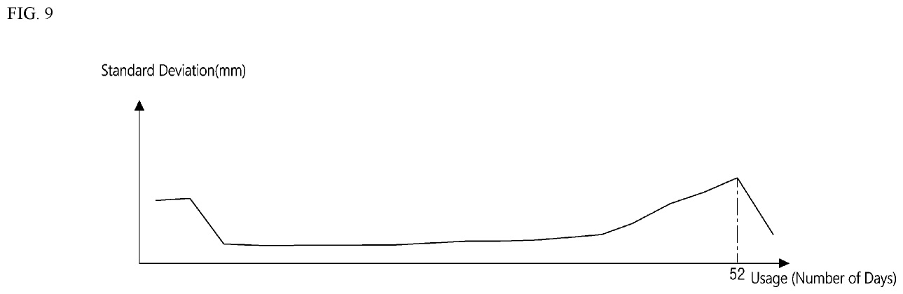

FIG. 9 is an exemplary schematic diagram illustrating a pack-specific standard deviation trend, which is derived based on experimental results for each pack installed in the inkjet head unit 140. Since the experimental results for each pack show a similar or identical shape to the broken line graph depicted in FIG. 9, only one representative experimental result is shown in the example of FIG. 9.

Each pack-specific landing standard deviation is represented as the average value of the standard deviations for the heads bundled in the corresponding pack. Similarly to what has been described above with regard to the head-specific standard deviation trend, it can be observed that the landing standard deviation for each pack decreases upon head replacement and increases over the period of usage. Head replacement information may be provided if the landing standard deviation exceeds a threshold value (e.g., 10 μm).

The comparison module 230 may determine which part of the graph in FIG. 9 the statistical value calculated by the statistical value calculation module 220 corresponds to, and whether the calculated statistical value exceeds the management threshold value. If it is determined, based on the previously and currently calculated statistical values, that the period of usage exceeds 52 days in the graph of FIG. 9, the processing module 240 may instruct the replacement of the inkjet head unit 140. Alternatively, the processing module 240 may also instruct the replacement of the corresponding pack.

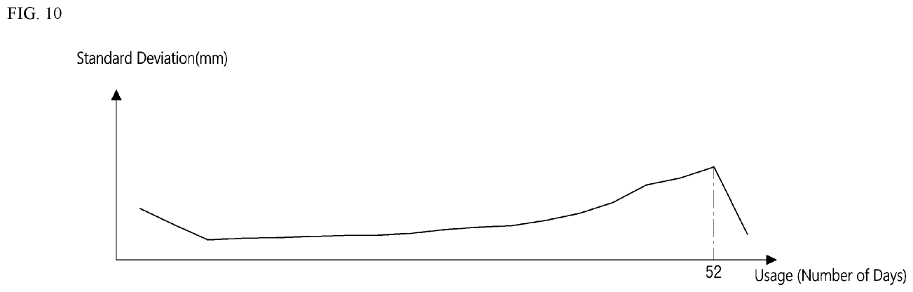

FIG. 10 is an exemplary diagram showing a color-specific standard deviation trend, which is derived based on experimental results for a plurality of packs provided in the inkjet head unit 140 for the respective colors. Since the experimental results for packs for different colors show a similar or identical shape to the broken line graph depicted in FIG. 10, only one representative experimental result is shown in the example of FIG. 10.

Each color-specific landing standard deviation is represented as the average value of the standard deviations for the packs of the corresponding color. Similarly to what has been described above with regard to the head-specific and pack-specific standard trends, it can be observed that the landing standard deviation for each color decreases upon head replacement and increases over the period of usage.

The comparison module 230 may determine which part of the graph in FIG. 10 the statistical value calculated by the statistical value calculation module 220 corresponds to, and whether the calculated statistical value exceeds the management threshold value. If it is determined, based on the previously and currently calculated statistical values, that the period of usage exceeds 52 days in the graph of FIG. 10, the processing module 240 may instruct the replacement of the inkjet head unit 140. Alternatively, the processing module 240 may also instruct the replacement of the corresponding pack.

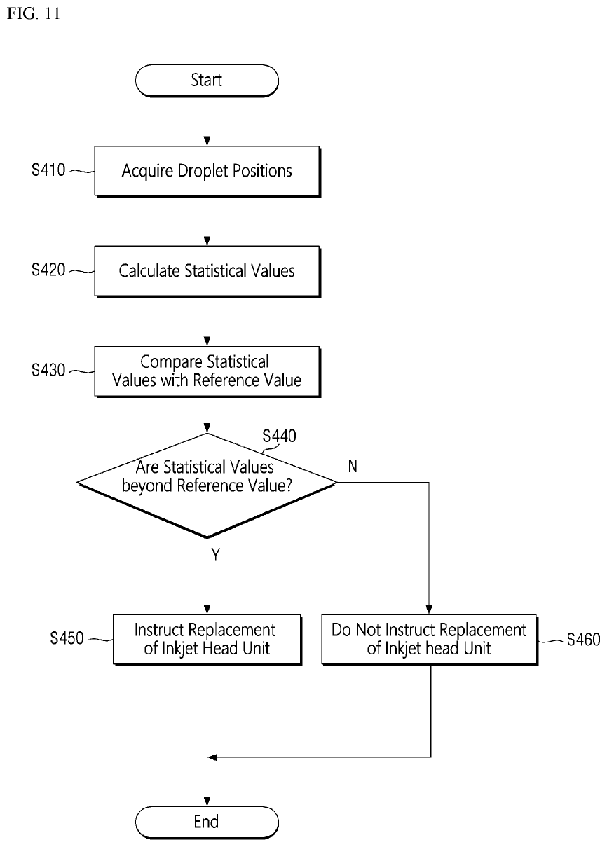

An inkjet head quality maintenance method of the control unit 170 will hereinafter be described. FIG. 11 is a flowchart illustrating the operating method of the control unit that constitutes the substrate treating apparatus.

Referring to FIG. 11, the droplet position acquisition module 210 acquires droplet position information for each droplet D ejected onto the dummy substrate F, in coordination with the measurement module 122 and the vision module 123 (S410). When a plurality of droplets D are ejected onto the dummy substrate F, which is provided within the measurement module 122, and the positions of the plurality of droplets D are measured by the vision module 123, the droplet position acquisition module 210 may acquire the results of the measurement as the droplet position information.

Thereafter, the statistical value calculation module 220 calculates statistical values related to the results of the measurement performed by the droplet position acquisition module 210 for the landing positions of the plurality of droplets D (S420).

The statistical value calculation module 220 may calculate the standard deviations for the respective packs provided within the inkjet head unit 140 as statistical values. The statistical value calculation module 220 may also calculate the standard deviations for the respective head modules within each pack as statistical values. The statistical value calculation module 220 may also calculate the standard deviations for the respective colors as statistical values.

However, the present disclosure is not limited to this. The statistical value calculation module 220 may also calculate the standard deviation solely for a particular pack within the inkjet head unit 140 as a statistical value. Alternatively, the statistical value calculation module 220 may also calculate the standard deviation solely for a particular head module provided within a particular pack as a statistical value. Yet alternatively, the statistical value calculation module 220 may also calculate the standard deviation solely for a particular color as a statistical value.

In cases where the statistical value calculation module 220 calculates the standard deviations for the respective packs within the inkjet head unit 140, for the respective head modules within each of the packs, and for the respective colors as statistical values, the following procedure may be followed.

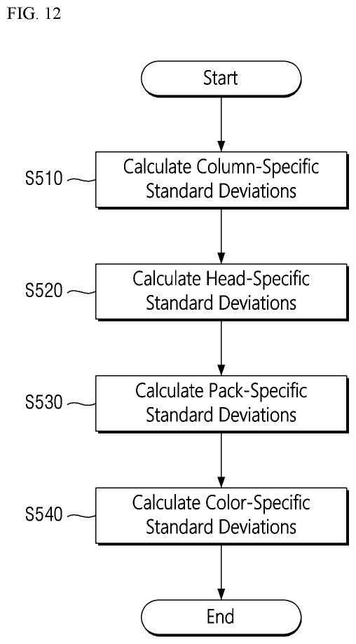

FIG. 12 is a flowchart illustrating a statistical value calculation method of the statistical value calculation module 220 that constitutes the control unit 170.

Referring to FIG. 12, first, the statistical value calculation module 220 calculates column-specific standard deviations for each head module, which includes a plurality of nozzles arranged in multiple rows and columns (S510).

Thereafter, the statistical value calculation module 220 calculates the standard deviation for each head module based on the average value of the column-specific standard deviations (S520).

Thereafter, the statistical value calculation module 220 calculates the standard deviation for each pack based on the average value of the standard deviations for the respective head modules (S530).

Thereafter, the statistical numerical calculation module 220 distinguishes the multiple packs provided within the inkjet head unit 140 by color, and calculates the standard deviation for each color (S540).

Referring back to FIG. 11, once statistical values such as head-specific standard deviations, pack-specific standard deviations, and color-specific standard deviations are calculated by the statistical numerical calculation module 220, the comparison module 230 compares the calculated statistical values to the management threshold value to determine whether the calculated statistical values exceed the management threshold value (S430 and S440).

If any one of the head-specific standard deviations, pack-specific standard deviations, and color-specific standard deviations are determined by the comparison module 230 to exceed the management threshold value, the processing module 240 may instruct the replacement of the inkjet head unit 140 (S450). In this case, if all the head-specific standard deviations, pack-specific standard deviations, and color-specific standard deviations do not exceed the management threshold value, the processing module 240 may not instruct the replacement of the inkjet head unit 140 (S460).

However, the present disclosure is not limited to this. Alternatively, if all the head-specific standard deviations, pack-specific standard deviations, and color-specific standard deviations are determined by the comparison module 230 to exceed the management threshold value, the processing module 240 may also instruct the replacement of the inkjet head unit 140. In this case, if any one of the head-specific standard deviations, pack-specific standard deviations, and color-specific standard deviations does not exceed the management threshold value, the processing module 240 may not instruct the replacement of the inkjet head unit 140.

Meanwhile, the processing module 240 may instruct the replacement of only a particular part within the inkjet head unit 140 if any one of the head-specific standard deviations, pack-specific standard deviations, and color-specific standard deviations are determined by the comparison module 230 to exceed the management threshold value.

For example, if a particular head-specific standard deviation is determined to exceed the management threshold value, the processing module 240 may instruct the replacement of only the corresponding head module within the inkjet head unit 140. Alternatively, if a particular pack-specific standard deviation exceeds the management threshold value, the processing module 240 may instruct the replacement of only the corresponding pack within the inkjet head unit 140. Alternatively, if a particular color-specific standard deviation exceeds the management threshold value, the processing module 240 may instruct the replacement of only the pack(s) of the corresponding color within the inkjet head unit 140.

Meanwhile, the factors for determining whether to replace the inkjet head unit 140 are not limited to statistical values. In other words, other factors, such as the number of droplet ejections, may also be used in conjunction with statistical values. In this case, even if the statistical values exceed the management threshold value, the processing module 240 may opt against instructing the replacement of the inkjet head unit 140 and may modify the management threshold value instead if other factors such as the number of droplet ejections do not exceed their respective threshold values.

Embodiments of the present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. A substrate treating apparatus comprising:
a process treatment unit supporting a substrate;
an inkjet head unit ejecting a substrate treating solution onto the substrate in the form of a droplet;
a gantry unit moving the inkjet head unit; and
a control unit controlling the inkjet head unit,
wherein the control unit determines whether to replace the inkjet head unit based on a position reproducibility of the droplet.

2. The substrate treating apparatus of claim 1, wherein the control unit calculates statistical values based on positions of a plurality of droplets and determines whether to replace the inkjet head unit based on the statistical values.

3. The substrate treating apparatus of claim 1, wherein
the inkjet head unit includes a plurality of packs,
each of the packs includes a plurality of head modules,
each of the head modules includes a plurality of nozzles, and
the packs are classified into multiple groups depending on colors of the substrate treating solution.

4. The substrate treating apparatus of claim 3, wherein the control unit calculates head-specific standard deviations for the nozzles within each of the head modules.

5. The substrate treating apparatus of claim 3, wherein the control unit calculates pack-specific standard deviations for the head modules and uses the pack-specific standard deviations as the statistical values.

6. The substrate treating apparatus of claim 3, wherein the control unit calculates color-specific standard deviations for the packs and uses the color-specific standard deviations as the statistical values.

7. The substrate treating apparatus of claim 2, wherein the control unit uses standard deviations as the statistical values.

8. The substrate treating apparatus of claim 1, wherein the control unit includes a droplet position acquisition module, which acquires positions of a plurality of droplets, a statistical value calculation module, which calculates statistical values based on the positions of the droplets, a comparison module, which compares the statistical value with a threshold value, and a processing module, which instructs the replacement of the inkjet head unit if the statistical values exceed the threshold value.

9. The substrate treating apparatus of claim 8, wherein the statistical value calculation module calculates head-specific standard deviations for a plurality of head modules with a plurality of nozzles, pack-specific standard deviations for a plurality of packs with a plurality of head modules, and color-specific standard deviations by classifying the plurality of packs by color.

10. The substrate treating apparatus of claim 9, wherein the statistical value calculation module calculates the head-specific standard deviations, then the pack-specific standard deviations, and then the color-specific standard deviations.

11. The substrate treating apparatus of claim 10, wherein the statistical value calculation module calculates the pack-specific standard deviations based on the head-specific standard deviations and calculates the color-specific standard deviations based on the pack-specific standard deviations.

12. The substrate treating apparatus of claim 9, wherein the comparison module determines whether each of the head-specific standard deviations, pack-specific standard deviations, and color-specific standard deviations exceed the threshold value.

13. The substrate treating apparatus of claim 12, wherein if any one of the head-specific standard deviations, pack-specific standard deviations, and color-specific standard deviations are determined to exceed the threshold value, the processing module instructs the replacement of a corresponding component within the inkjet head unit.

14. The substrate treating apparatus of claim 1, wherein the control unit determines whether to replace the inkjet head unit based on the position reproducibility by comparing a position of the droplet with a reference position.

15. The substrate treating apparatus of claim 1, wherein the control unit determines whether to replace the inkjet head unit based on droplets ejected onto a dummy substrate, which is provided separately from the substrate.

16. The substrate treating apparatus of claim 15, wherein the dummy substrate is a hydrophobically coated substrate.

17. The substrate treating apparatus of claim 1, further comprising:
a maintenance unit disposed near the process treatment unit for the inspection of the inkjet head unit,
wherein the control unit determines whether to replace the inkjet head unit using a dummy substrate, which is provided in the maintenance unit.

18. A control unit for controlling an inkjet head unit, which ejects a substrate treating solution onto a substrate for treating the substrate, comprising:
a droplet position acquisition module acquiring positions of a plurality of droplets;
a statistical value calculation module calculating statistical values related to a position reproducibility of the droplets based on the positions of the droplets;
a comparison module comparing the statistical values with a threshold value; and
a processing module instructing the replacement of the inkjet head unit if the statistical values are determined to exceed the threshold value.

19. The control unit of claim 18, wherein
the droplets are ejected onto a dummy substrate, which is provided separately from the substrate, and
the dummy substrate is a hydrophobically coated substrate.

20. A substrate treating apparatus comprising:
a process treatment unit supporting a substrate;
an inkjet head unit ejecting a substrate treating solution onto the substrate in the form of a droplet;
a gantry unit moving the inkjet head unit; and
a control unit controlling the inkjet head unit,
wherein
the control unit determines whether to replace the inkjet head unit based on a position reproducibility of the droplet,
the inkjet head unit includes a plurality of packs,
each of the packs includes a plurality of head modules,
each of the head modules includes a plurality of nozzles,
the packs are classified into multiple groups depending on colors of the substrate treating solution,
the control unit includes a droplet position acquisition module, which acquires positions of a plurality of droplets, a statistical value calculation module, which calculates statistical values based on the positions of the droplets, a comparison module, which compares the statistical value with a threshold value, and a processing module, which instructs the replacement of the inkjet head unit if the statistical values exceed the threshold value,
the statistical value calculation module calculates head-specific standard deviations for a plurality of head modules with a plurality of nozzles, pack-specific standard deviations for a plurality of packs with a plurality of head modules, and color-specific standard deviations by classifying the plurality of packs by color,
the statistical value calculation module calculates the pack-specific standard deviations based on the head-specific standard deviations and calculates the color-specific standard deviations based on the pack-specific standard deviations,
the comparison module determines whether each of the head-specific standard deviations, pack-specific standard deviations, and color-specific standard deviations exceed the threshold value, and
if any one of the head-specific standard deviations, pack-specific standard deviations, and color-specific standard deviations is determined to exceed the threshold value, the processing module instructs the replacement of a corresponding component within the inkjet head unit.
